(19) United States
(12) Patent Application Publication
(10) Pub. No.: US 2013/0098652 A1
(43) Pub. Date: Apr. 25, 2013

(54) DEVICE HOUSING AND METHOD FOR MAKING THE SAME

(71) Applicants: QIU-JIANG XU, Shenzhen City (CN); SHU-XIANG ZHOU, Shenzhen City (CN); HE-XIAN LIN, Shenzhen City (CN); PO-FENG HO, Shindian (TW)

(72) Inventors: QIU-JIANG XU, Shenzhen City (CN); SHU-XIANG ZHOU, Shenzhen City (CN); HE-XIAN LIN, Shenzhen City (CN); PO-FENG HO, Shindian (TW)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/572,801

(22) Filed: Aug. 13, 2012

(30) Foreign Application Priority Data
Oct. 21, 2011 (CN) 201110322779.5

(51) Int. Cl. H05K 5/00; B29C 31/08

(52) U.S. Cl. 174/50; 264/261

(57) ABSTRACT

A device housing includes a main body, and a display window mounted on the main body. A mounting gap is defined between the main body and the display window. The device housing further includes a decorative member jointing with the main body and the display window and covering the mounting gap. The decorative member is made of thermoset resin or polyurethane coating. A method for making the device housing is also provided.

### BACKGROUND

1. Technical Field

The present disclosure relates to device housing and a method for making the device housing.

2. Description of Related Art

Housings of electronic devices commonly include several housing elements, such as an upper cover and a lower cover. The housing elements may be first molded and then incorporated together. To incorporate the housing elements together, the housing elements include locking members or catching members thereon. However, it is time-consuming and costly to form the locking or catching members and to configure the housing elements. Furthermore, mounting gaps can form between the housing elements. The mounting gaps affect the appearance of housings and allow water and dust to enter the housings.

Therefore, there is room for improvement within the art.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is an isometric view of an exemplary embodiment of a device housing including a main body, a display window, and a decorative member.

FIG. 2 is an isometric view of the main body and the display window.

FIG. 3 is a cross-sectional view of the device housing shown in FIG. 1 take along line III-III except the decorative member.

FIG. 4 is a cross-sectional view of the device housing shown in FIG. 1 take along line III-III.

FIG. 5 is a cross-sectional view of an exemplary embodiment of a mold used for making the device housing.

FIG. 6 is a cross-sectional view of the mold shown in FIG. 5 in use.

### DETAILED DESCRIPTION

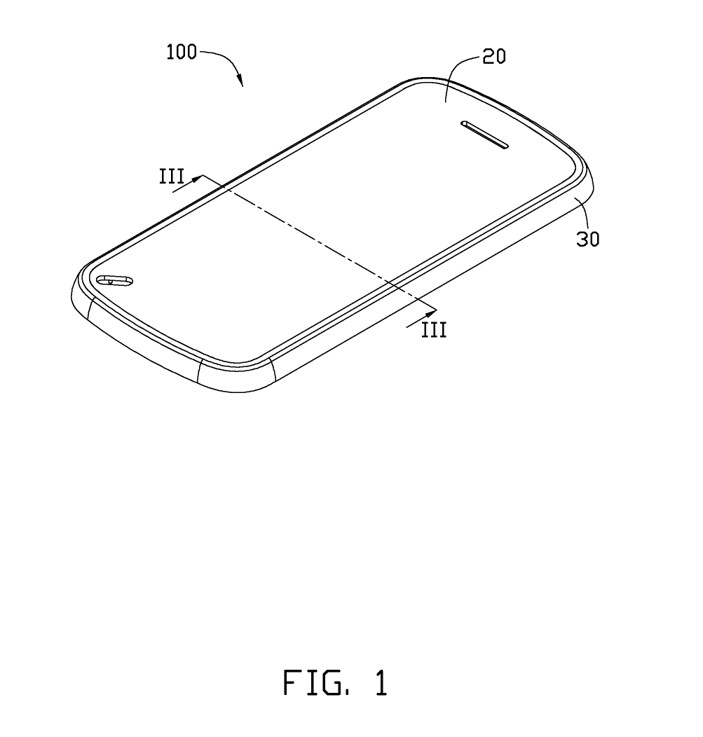

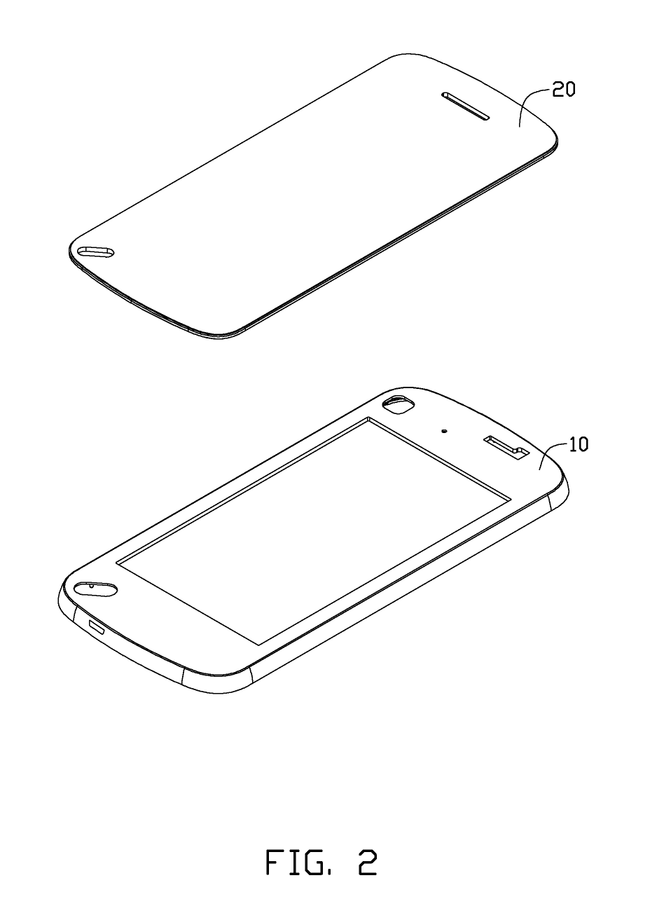

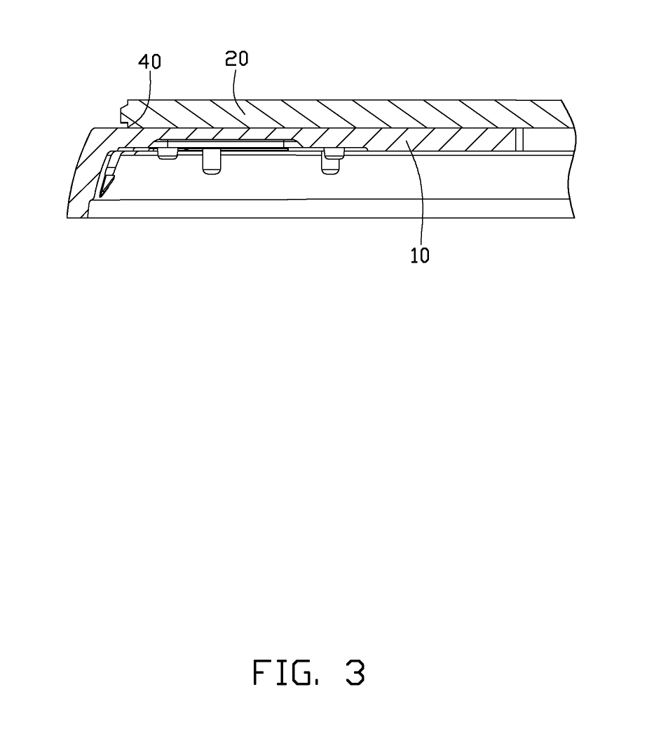

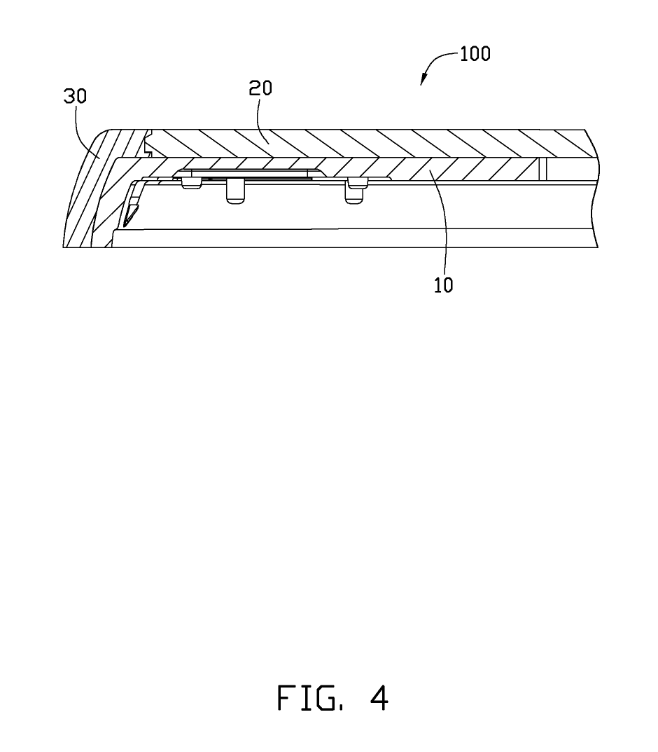

Referring to FIGS. 1-4, a device housing 100 according to an exemplary embodiment includes a main body 10, and a display window 20 mounted on the main body 10. A mounting gap 40 is formed at the junction between the main body 10 and the display window 20. The device housing 100 further includes a decorative member 30 formed on the main body 10 and the display window 20 and covers the mounting gap 40. The device housing 100 may be a mobile phone.

The main body 10 may be made of thermoplastic resins. The thermoplastic resin may be one or more selected from a group consisting of polyethylene (PE), polyvinyl chloride (PVC), polypropylene (PP), polystyrene (PS), acrylonitrile-butadiene-styrene (ABS), nylon, polycarbonate (PC), polyurethane (PU), polyfluortetraethylene (PTFE), and polyethylene glycol terephthalate (PET).

The display window 20 may be made of transparent thermoplastic resins or glass. The transparent thermoplastic resin may be one or more ingredients selected from a group consisting of PC, ABS, polymethylmethacrylate (PMMA), polyphenylene sulfide (PPS), and polyethylene glycol tetramethylene (PBT). In the embodiment, the display window 20 is made of a mixture of PC and ABS.

The decorative member 30 is made of thermoset resin, or made of polyurethane coating (or paint). The thermoset resin may be epoxy resin. Pigments can be added to the thermoset resin. The pigments render the decorative member 30 desired colors. The polyurethane coating may be two-component polyurethane coating containing isocyanate prepolymer and hydroxyl radical resin which has good mechanical property. The two-component polyurethane coating may be acrylic polyurethane coating.

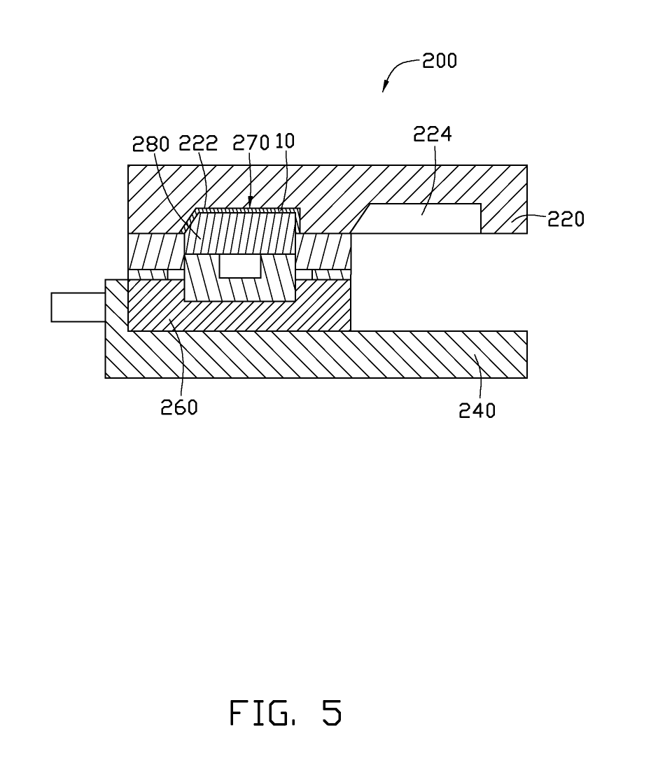

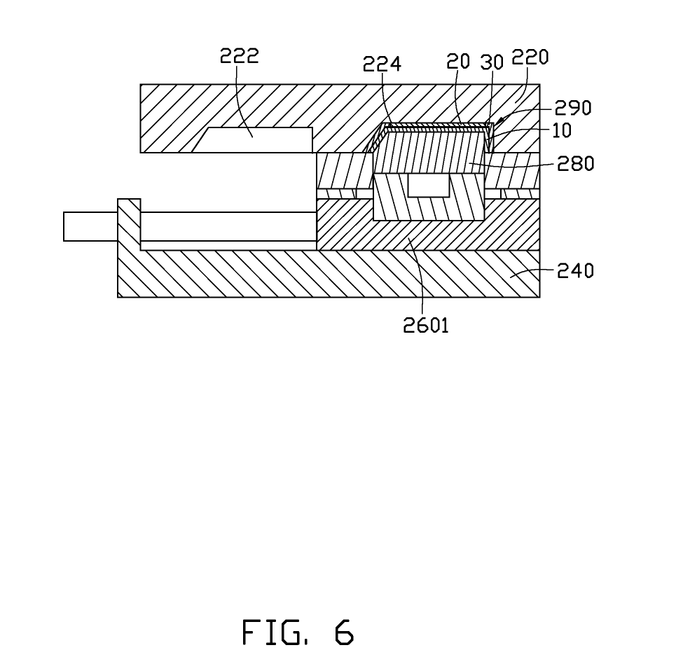

Referring to FIGS. 5 and 6, a method for making the device housing 100 may include the following steps.

A mold 200 is provided. The mold 200 includes an upper mold 220, a lower mold 240, a slider 260, and a core 280.

The upper mold defines a first cavity 222 and a second cavity 224. The slider 260 is movably mounted in the lower mold 240. The core 280 is fastened on the slider 260.

When the slider 260 moves the core 280 to the first cavity 222, the upper mold 220 and the lower mold 240 are closed, thereby a first receiving space 270 is formed in the first cavity 222. The first receiving space 270 is then evacuated by a vacuum pumping device (not shown). Molten thermoplastics resins are molded in the evacuated first receiving space 270 and then cooled to form the main body 10.

The upper mold 220 is opened to remove the main body 10. The display window 20 is provided and adhered to the main body 10 by adhesives, such as glue. The display window 20 incorporated main body 10 is located on the core 280. Referring to FIG. 6, the slider 260 moves the core 280 together with the display window 20 incorporated main body 10 to the second cavity 224. The upper mold 220 and the lower mold 240 are closed once more, thereby a second receiving space 290 is formed in the second cavity 224. The second receiving space 290 is then evacuated by the vacuum pumping device (not shown). Thermoset resins or the two-component polyurethane coating is molded in the evacuated second receiving space 290 and then heated to form the decorative member 30. The two-component polyurethane coating is a reactive coating, isocyanate prepolymer and hydroxyl radical resin can be mixed in the second receiving space 290 to take a reaction and then cross link and solidify to form the decorative member 30. After the decorative member 30 is formed, the upper mold 220 is opened again to remove the device housing 100.

The device housing 100 of the exemplary embodiment forms no mounting gaps by molding the decorative member 30 using thermoset resin or paint. Furthermore, the decorative member 30 can decorate the device housing 100. Thus a painting process for decorating the device housing 100 can be omitted and the cost of the device housing 100 is decreased. Additionally, during the molding process, the decorative member 30 is molded after the molding of the main body 10 which need a higher temperature and a higher pressure, thus the main body 10 and the display window 20 will not be deformed due to heat during the molding of the decorative member 30.

The main body 10 can also be made of metal, such as stainless steel. When the main body 10 is made of metal, the molding of the main body 10 is omitted.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A device housing, comprising:
a main body;
a display window mounted on the main body, a mounting gap being defined between the main body and the display window; and
a decorative member jointing with the main body and the display window and covering the mounting gap, the decorative member being made of thermoset resin or polyurethane coating.

2. The device housing as claimed in claim 1, wherein the thermoset resin is epoxy resin.

3. The device housing as claimed in claim 1, wherein the polyurethane coating is two-component polyurethane coating.

4. The device housing as claimed in claim 1, wherein the main body is made of thermoplastic resin.

5. The device housing as claimed in claim 4, wherein the thermoplastic resin is one or more ingredients selected from a group consisting of polyethylene, polyvinyl chloride, polypropylene, polystyrene, acrylonitrile-butadiene-styrene, nylon, polycarbonate, polyurethane, polyfluortetraethylene, and polyethylene glycol terephthalate.

6. The device housing as claimed in claim 1, wherein the main body is made of stainless steel.

7. The device housing as claimed in claim 1, wherein the display window is made of transparent thermoplastic resin or glass.

8. The device housing as claimed in claim 7, wherein the transparent thermoplastic resin is one or more ingredients selected from a group consisting of polycarbonate, acrylonitrile-butadiene-styrene, polymethylmethacrylate, polyphenylene sulfide, and polyethylene glycol tetramethylene.

9. A method for making a device housing, comprising:
providing a main body having a display window mounted thereon, the main body and the display window defining a mounting gap at the junction of the main body and the display window;
providing a mold comprising an upper mold, a lower mold, and a core, the upper mold defining a cavity, the main body and the display window being located on the core, the upper mold and the lower mold being closed to form a receiving space in the cavity;
forming a decorative member to joint with the main body and the display window and covering the mounting gap by molding thermoset resin or polyurethane coating in the receiving space and heating the thermoset resin or polyurethane coating.

10. The method as claimed in claim 9, wherein the thermoset resin is added with pigment.

11. The method as claimed in claim 9, wherein the thermoset resin is epoxy resin.

12. The method as claimed in claim 9, wherein the polyurethane coating is two-component polyurethane coating.

13. The method as claimed in claim 9, wherein the display window is made of transparent thermoplastic resin or glass.

14. The method as claimed in claim 9, wherein the main body is made of thermoplastic resin or stainless steel.
